(19) United States
(12) Patent Application Publication
(10) Pub. No.: US 2007/0146008 A1
(43) Pub. Date: Jun. 28, 2007

(54) Semiconductor circuit comprising vertical transistor

(76) Inventors: Nam-Kyun Tak, Suwon-si (KR); Ki-Whan Song, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/581,390

(22) Filed: Oct. 17, 2006

(30) Foreign Application Priority Data
Dec. 22, 2005 (KR) 10-2005-0127690

(51) Int. Cl. H03K 19/094

(52) U.S. Cl. 326/83

(57) ABSTRACT

A semiconductor circuit comprising a vertical transistor is disclosed. A differential amplifier circuit comprises a pair of amplification transistors, wherein the pair of amplification transistors comprises a first amplification transistor adapted to receive, amplify, and output a differential input signal. The first amplification transistor is a first vertical transistor comprising a first top and a first bottom, and the first top is a first drain of the first vertical transistor and the first bottom is a first source of the first vertical transistor. The differential amplifier circuit further comprises a current source electrically disposed between the pair of amplification transistors and a second power supply to form a current path between a first power supply and the second power supply.

### BACKGROUND OF THE INVENTION

1. Field of the Invention

Embodiments of the invention relate to semiconductor circuits. In particular, embodiments of the invention relate to a differential amplifier circuit comprising a vertical transistor and a logic circuit comprising a vertical transistor.

This application claims priority to Korean Patent Application No. 10-2005-0127690, filed on Dec. 22, 2005, the subject matter of which is hereby incorporated by reference in its entirety.

2. Description of the Related Art

The development of semiconductor technology has brought increases in the integration density and operating speed of semiconductor memory devices. Integration density in particular has been actively researched since integration density is directly linked with cost of a semiconductor device.

Methods of connecting a cell capacitor to the top of a vertical transistor have been suggested as methods for achieving high integration density in a semiconductor device. Unlike a conventional transistor comprising a horizontal channel with respect to a working surface of a substrate, a vertical transistor comprises a channel formed in a vertical direction with respect to the working surface of a substrate on which the vertical transistor is formed. Thus, a vertical transistor may be referred to as a vertical channel transistor. In addition, a source and a drain of the vertical transistor are separated from one another in the vertical direction with respect to the working surface of the substrate on which the vertical transistor is formed.

A vertical transistor occupies less surface area on a substrate than a conventional transistor comprising a horizontal channel. Accordingly, a technique for forming a memory cell using a vertical transistor is essential to successfully fabricating 4F² dynamic random access memory (DRAM). In 4F² DRAM, a single memory cell is formed in a region of a substrate having a surface area of 4F², e.g., an area of 2F×2F, wherein F is the minimum pitch size available in lithography.

### SUMMARY OF THE INVENTION

Since a vertical transistor occupies less surface area than a conventional horizontal channel transistor, when a vertical transistor is used in fabricating a peripheral circuit such as an amplifier circuit or a logic circuit, in addition to a memory cell, the surface area of a substrate occupied by the circuit can be reduced.

Embodiments of the invention provide a semiconductor circuit comprising a wiring arrangement that may improve electrical characteristics of the circuit, which comprises a vertical transistor. A vertical transistor occupies less area on a substrate than a conventional horizontal transistor, so using vertical transistors in the semiconductor circuit may increase the integration density of a semiconductor device in which the semiconductor circuit is formed.

In one embodiment, the invention provides a differential amplifier circuit comprising a pair of amplification transistors, wherein the pair of amplification transistors comprises a first amplification transistor adapted to receive, amplify, and output a differential input signal. The first amplification transistor is a first vertical transistor comprising a first top and a first bottom, and the first top is a first drain of the first vertical transistor and the first bottom is a first source of the first vertical transistor. The differential amplifier circuit further comprises a current source electrically disposed between the pair of amplification transistors and a second power supply to form a current path between a first power supply and the second power supply.

In one embodiment, the invention provides a semiconductor logic circuit comprising a first vertical transistor comprising a first top and a first bottom, wherein the first top is a first drain of the first vertical transistor and the first bottom is a first source of the first vertical transistor; and, a second vertical transistor comprising a second top and a second bottom, wherein the second top is a second drain of the second vertical transistor and the second bottom is a second source of the second vertical transistor. The first and second vertical transistors are adapted to generate a logical output signal in response to a first logical input signal.

In yet another embodiment, the invention provides a semiconductor logic circuit adapted to output a logical output signal in accordance with a first logical input signal. The semiconductor logic circuit comprises a first vertical transistor comprising a first top and a first bottom, wherein the first vertical transistor is a first P-channel transistor, the first top is connected to a first node, and the first bottom is connected to a second node having a higher potential than the first node. The semiconductor logic circuit further comprises a second vertical transistor comprising a second top and a second bottom, wherein the second vertical transistor is a first N-channel transistor, the second bottom is connected to a third node, and the second top is connected to a fourth node having a higher potential than the third node.

### BRIEF DESCRIPTION OF THE DRAWINGS

Embodiments of the invention will be described hereafter with reference to the accompanying drawings, in which like reference symbols indicate like or similar elements. In the drawings:

FIGS. 1 and 2 are schematic diagrams of a conventional vertical transistor;

FIG. 3 is a circuit diagram of a differential amplifier in accordance with an embodiment of the invention;

FIG. 4 is a perspective view of the differential amplifier of FIG. 3 formed on a silicon substrate in accordance with an embodiment of the invention;

FIG. 5 is a circuit diagram of a differential amplifier in accordance with another embodiment of the invention;

FIG. 6 is a perspective view of the differential amplifier of FIG. 5 formed on a silicon substrate in accordance with another embodiment of the invention;

FIG. 7 is a circuit diagram of an inverter in accordance with an embodiment of the invention;

FIG. 8 is a circuit diagram of a NAND gate in accordance with an embodiment of the invention;

FIG. 9 is a circuit diagram of a NOR gate in accordance with an embodiment of the invention;

FIG. 10A is a diagram of a vertical transistor that does not comprise an offset silicon area on a top of a channel region;

FIG. 10B is a diagram of a vertical transistor comprising an offset silicon area on a top of a channel region; and,

FIG. 11 is a graph of current versus gate voltage for a vertical transistor comprising the offset silicon area and for a vertical transistor that does not comprise the offset silicon area.

### DESCRIPTION OF EMBODIMENTS

As used herein, when a first element is said to be formed “on” a second element, the first element may be formed directly on the second element, or intervening elements may be present. In addition, terms such as “first,” “second,” etc., are used herein for convenience of description and do not limit the invention.

Before describing embodiments of the invention, a conventional vertical transistor will be described herein.

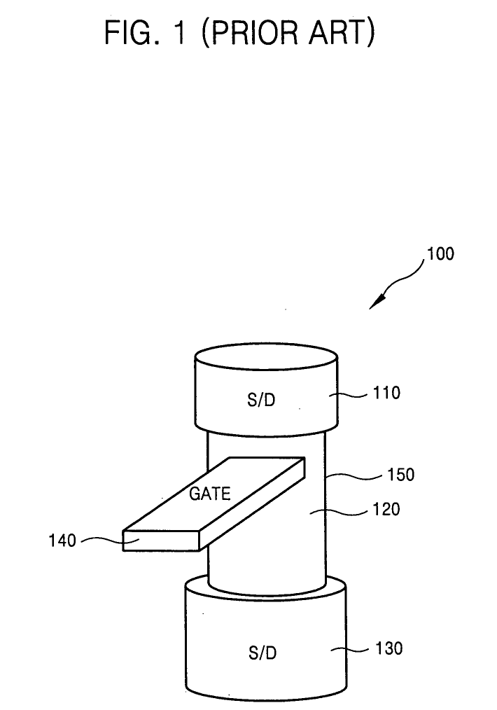

FIGS. 1 and 2 are schematic diagrams of a conventional vertical transistor 100. FIG. 1 is a perspective view of vertical transistor 100 and FIG. 2 is a cross-sectional view of a plurality of vertical transistors, taken in a vertical direction with respect to a working surface of a silicon (Si) substrate 160.

Referring to FIGS. 1 and 2, vertical transistor 100 comprises a channel region 120, which is formed in the vertical direction (i.e., in a direction substantially perpendicular to a working surface of silicon substrate 160), unlike a conventional transistor, which comprises a channel formed in a horizontal direction (i.e., in a direction substantially parallel with a working surface of a corresponding substrate). Referring to FIG. 2, channel region 120 of vertical transistor 100 is formed to have a cylindrical shape and is formed on silicon (Si) substrate 160. In addition, a top and a bottom of channel 120 are doped with n-type or p-type impurities to form source/drain (S/D) regions. A bottom 130 is formed by doping a region of silicon substrate 160 below channel region 120 with N-type or P-type impurities. A top 110 is formed by doping silicon substrate 160 above channel region 120 with N-type or P-type impurities. In addition, a gate insulating layer 150 is formed to surround channel region 120, and a gate region 140 is formed on gate insulating layer 150. Gate region 140 may be formed using polysilicon. Vertical transistor 100 comprising a cylindrical-shaped channel region 120, as shown in FIGS. 1 and 2, may be referred to as a vertical pillar transistor.

Referring to FIG. 2, four vertical transistors, that is, vertical transistors 100, 100a, 100b, and 100c, are formed on silicon substrate 160. S/D regions are formed at top 110 above channel region 120 and bottom 130 below channel region 120 of vertical transistor 100. When top 110 is the source of vertical transistor 100, bottom 130 is the drain, and when top 110 is the drain of vertical transistor 100, bottom 130 is the source.

A contact 111 is used to apply a supply voltage to top 110 or to connect top 110 to another circuit. Contact 111 may be formed using metal, such as aluminum. A wiring 142 connects a gate region 140 to another circuit. Wiring 142 may be formed using metal or doped polysilicon.

A conventional transistor comprising a horizontal channel comprises a source and a drain, wherein the source/drain regions are symmetrical with one another. Thus, electrical characteristics of a circuit comprising the conventional transistor do not change in accordance with which region of the two symmetrical source/drain regions is the source and which is the drain. In a vertical transistor, however, a region above the channel region and a region below the channel region cannot be symmetrically formed (i.e., cannot be manufactured to be the same in terms of processes), so electrical characteristics of the circuit in which the vertical transistor is formed change in accordance with which region of the vertical transistor is the source and which is the drain. That is, which of the region above the channel region (i.e., the top) and the region below the channel region (i.e., the bottom) is the source and which is the drain. Accordingly, the relative positions of the source and the drain in a vertical transistor (i.e., at the top or at the bottom) must be established in such a way that the circuit comprising the vertical transistor will have beneficial electrical characteristics.

Therefore, embodiments of the invention, which will now be described hereafter, provide a wiring arrangement that establishes the positions of the source and the drain of a vertical transistor so that the circuit comprising the vertical transistor will have beneficial electrical characteristics.

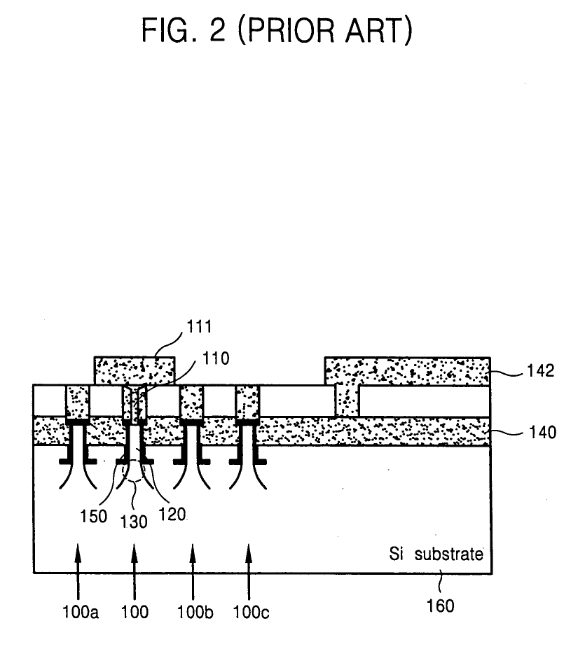

FIG. 3 is a circuit diagram of a differential amplifier 300 in accordance with an embodiment of the invention. Differential amplifier 300 comprises a pair of amplification transistors 310 and 320, a current source 330, and a load 340.

In the embodiment illustrated in FIG. 3, first and second amplification transistors 310 and 320 are implemented using first and second N-channel transistors (i.e., negative-channel metal-oxide semiconductor (NMOS) transistors), respectively. The drain of first amplification transistor 310 is connected to a first differential output node N1, the source of first amplification transistor 310 is connected to a common node N3, and the gate of first amplification transistor 310 is adapted to receive a first differential input signal Vin+. Additionally, the drain of second amplification transistor 320 is connected to a second differential output node N2, the source of second amplification transistor 320 is connected to common node N3, and the gate of second amplification transistor 320 is adapted to receive a second differential input signal Vin−.

Current source 330 comprises an N-channel transistor connected between common node N3 and a ground voltage. That is, current source 330 is electrically disposed between first and second amplification transistors 310 and 320 and the ground voltage. As used herein, if a first element is “electrically disposed between” a second element and a third element, then the first element is a part of the electrical path that exists between the second element and the third element. The N-channel transistor of current source 330 comprises a drain connected to common node N3, a gate adapted to receive a bias voltage Vb, and a source connected to the ground voltage.

Load 340 comprises a first load transistor 345 implemented using an N-channel transistor and a second load transistor 350 also implemented using an N-channel transistor. The drains and gates of first and second load transistors 345 and 350 are each respectively connected to a first power supply Vdd, and the sources of first and second load transistors 345 and 350 are connected to first and second differential output nodes N1 and N2, respectively. The structure of differential amplifier 300, as described above, is similar (i.e., analogous) to the structure of a conventional differential amplifier. However, differential amplifier 300, in accordance with an embodiment of the invention, comprises vertical transistors. Furthermore, the wiring of the terminals of transistors in differential amplifier 300 is arranged so that, with respect to each vertical transistor in differential amplifier 300, the positions of the source and the drain are established in a way that may improve the electrical characteristics of differential amplifier 300.

Contact resistance, capacitance, leakage current, and output resistance are factors considered in determining where to position the source and the drain of each vertical transistor of differential amplifier 300. In light of the previously mentioned factors, the drains of the vertical transistors of amplification transistors 310 and 320 are preferably disposed at the tops of the vertical transistors and the sources of the vertical transistors are preferably disposed at the bottoms of the vertical transistors, as will be discussed in more detail hereafter.

When contact resistance must exist at either a source or a drain of a transistor, the contact resistance preferably exists at the drain. If the contact resistance exists at the source, a voltage between the gate and the source of the transistor increases, which can cause electrical characteristics of the circuit in which the transistor is formed to deteriorate (i.e., causing characteristic deterioration).

Also, a gate-source/gate-drain overlap capacitance is greater at the bottom of a vertical transistor than at the top, and since it is advantageous to have a small drain capacitance, the drain is preferably disposed at the top of the vertical transistor.

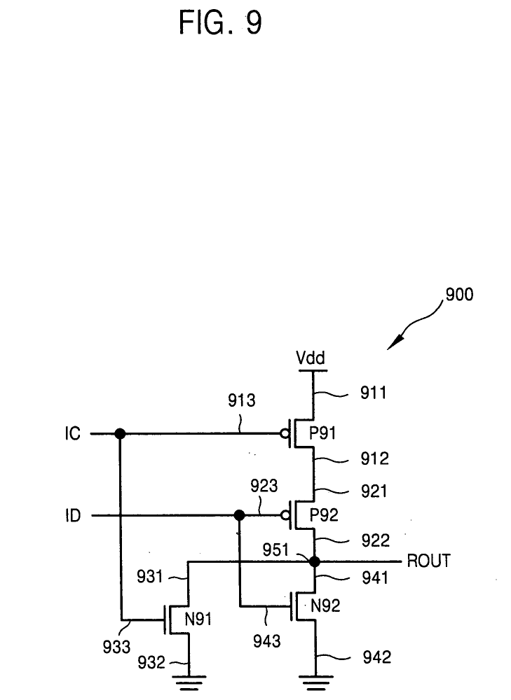

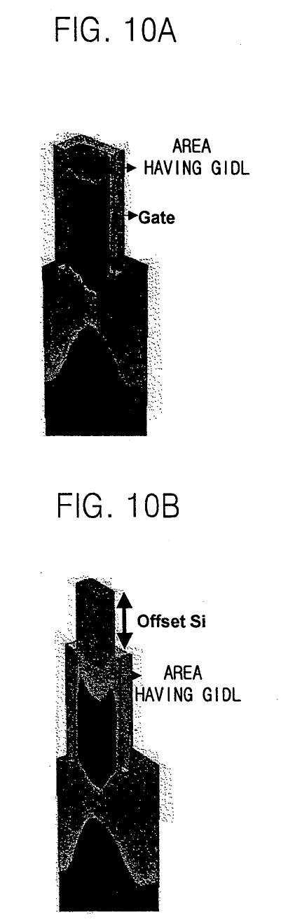

In addition, two methods of reducing leakage current are (1) forming an extended area of silicon to form an offset Si area at the top of a vertical transistor to prevent gate induced drain leakage (GIDL), and (2) decreasing doping concentration. The offset Si area will now be described in more detail with reference to FIGS. 10A and 10B.

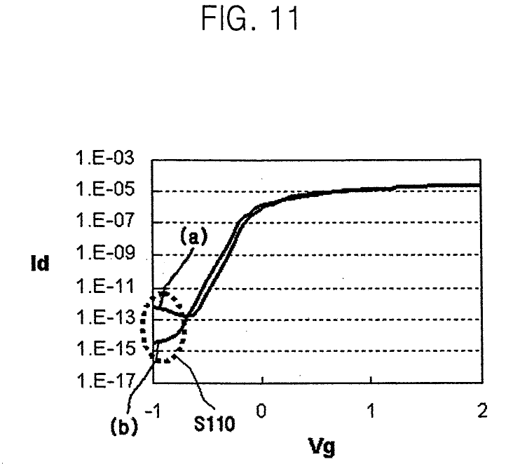

FIG. 10A is a diagram of a vertical transistor that does not comprise an offset Si area on the top of a channel region. FIG. 10B is a diagram of a vertical transistor comprising an offset Si area on the top of a channel region. FIG. 11 is a graph of current versus gate voltage when an offset Si area is not formed on the top of the channel region (as illustrated by the curve marked “(a)”) and when the offset Si area is formed on the top of the channel region (as illustrated by the curve marked “(b)”). In FIG. 11, the portion of the graph marked S110 indicates GIDL current. The graph of FIG. 11 shows that the GIDL current is less when the offset Si area is formed on the top of the channel region (see (b)) as compared to when the offset Si area is not formed on the top of the channel region (see (a)). Accordingly, the drain of a vertical transistor is preferably disposed at the top of the vertical transistor where the method for reducing leakage current using an offset Si area can be readily performed.

Additionally, since output resistance is great at the top of a vertical transistor where the doping concentration has been decreased to reduce GIDL, it is advantageous in terms of voltage gain to position the drains at the respective tops of the vertical transistors of amplification transistors 310 and 320.

In current source 330, which comprises at least one vertical transistor, it is also advantageous for the drain of the at least one vertical transistor to be at the top of the at least one vertical transistor since contact resistance is greater at the top than at the bottom. When a load transistor (a first load transistor 345 or a second load transistor 350) is an N-channel transistor, the top of a vertical transistor of the load transistor is preferably connected to a node having a higher potential than a node to which the bottom is connected so that the top of the vertical transistor will be the drain. In contrast, when a load transistor (a first load transistor 345 or a second load transistor 250) is a P-channel transistor, the bottom of a vertical transistor of the load transistor is preferably connected to a node having a higher potential than a node to which the top is connected so that the bottom will be the source of the vertical transistor and the top will be the drain.

Thus, to improve electrical characteristics of a differential amplifier, in accordance with the factors discussed above, wiring connections in the differential amplifier are preferably made such that the top of a vertical transistor in the differential amplifier becomes the drain of the vertical transistor and the bottom becomes the source. Accordingly, when the vertical transistor is an N-channel transistor, the top of the vertical transistor is preferably connected to a node having a higher potential than a node to which the bottom of the vertical transistor is connected so that the top becomes the drain of the vertical transistor and the bottom becomes the source. When the vertical transistor is a P-channel transistor, the bottom of the vertical transistor is preferably connected to a node having a higher potential than a node to which the top of the vertical transistor is connected so that the bottom becomes the source and the top becomes the drain.

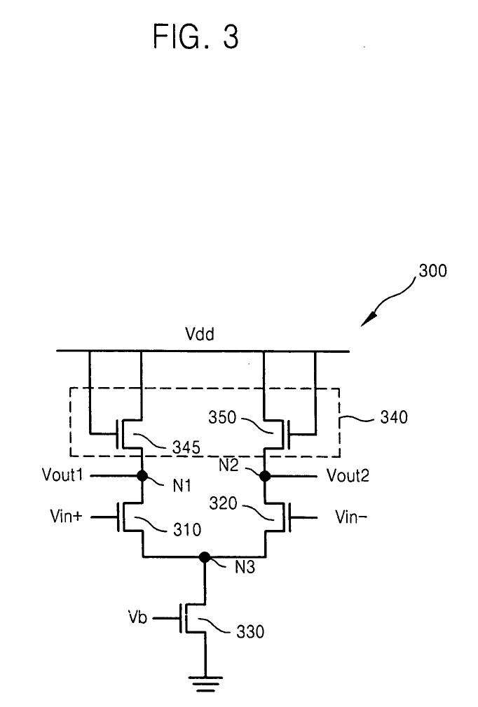

FIG. 4 is a perspective view of differential amplifier 300 formed on a silicon substrate in accordance with an embodiment of the invention. For the reasons discussed above, differential amplifier 300 is wired so that the drain of each vertical transistor in differential amplifier 300 is at the top of the vertical transistor and the source of each vertical transistor is at the bottom.

Referring to FIG. 4, amplification transistors 310 and 320, current source 330, and first and second load transistors 345 and 350 each comprise at least one vertical transistor, and each of those at least one vertical transistors is connected such that the top of the vertical transistor becomes the drain and the bottom becomes the source. In more detail, load 340 comprises four vertical transistors, i.e., four load transistors, which are first and second vertical load transistors 345′ and 350′. First load transistor 345 comprises first vertical load transistors 345′ and second load transistor 350 comprises second vertical load transistors 350′. Tops 341 and 351 of first and second vertical load transistors 345′ and 350′ are drains and are connected to a first power supply Vdd. Wiring 361 connects tops 341 and 351 of first and second vertical load transistors 345′ and 350′ to first power supply Vdd. Gates 342 of first and second vertical load transistors 345′ and 350′ are connected to first power supply Vdd through a wiring 362. Bottoms 343 of first vertical load transistors 345′ are sources and are connected to differential output node 381 through wiring 391. Bottoms (not shown) of second vertical load transistors 350′ are sources and are connected to differential output node 382 through wiring 392.

Additionally, each of amplification transistors 310 and 320 is a vertical transistor and respective tops 311 and 321 of amplification transistors 310 and 320 are respectively connected to corresponding differential output nodes 381 and 382, and respective bottoms 313 and 323 of amplification transistors 310 and 320 are connected to tops 331 of current source transistors 330′ through wirings 393 and 394. First differential input signal Vin+ is input to gate 312 of amplification transistors 310 and second differential input signal Vin− is input to gate 322 of amplification transistors 320.

Current source 330 comprises four vertical transistors, i.e., four current source transistors, which are current source transistors 330′. Bottoms 333 of current source transistors 330′ are connected to a second power supply (i.e., a ground voltage) GND through a wiring 395. A bias voltage Vb is input to gates 332 of current source transistors 330′. In the embodiment illustrated in FIG. 4, wirings 361, 362, 391, 392, 393, 394, and 395 may be formed from poly silicon or metal.

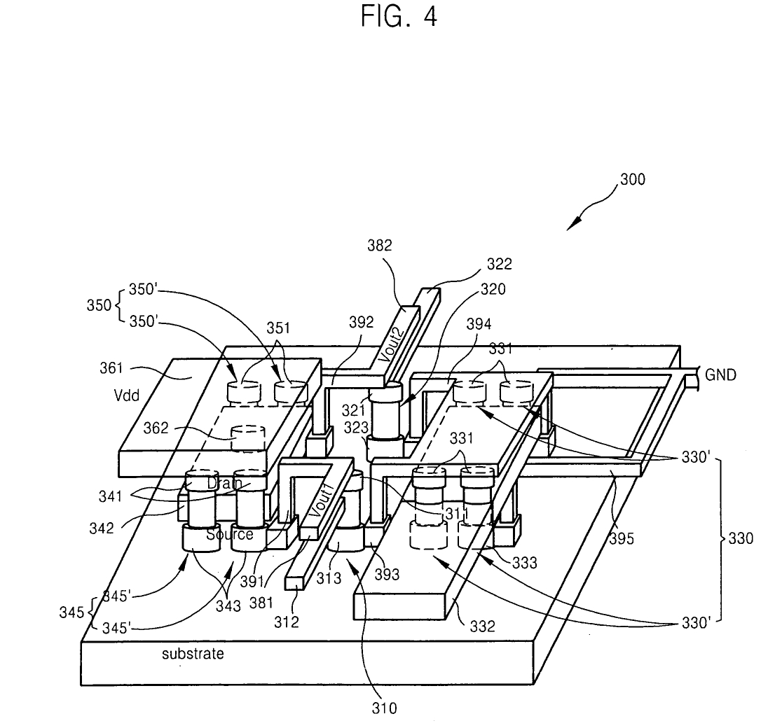

FIG. 5 is a circuit diagram of a differential amplifier 500 in accordance with another embodiment of the invention. Referring to FIG. 5, like differential amplifier 300 of FIG. 3, differential amplifier 500 comprises a pair of amplification transistors 310 and 320, current source 330, and a load 510. Load 510 comprises first load transistor 515 and second load transistor 520. While the gate and the drain of each of first and second load transistors 345 and 350 of differential amplifier 300 of FIG. 3 are connected to one another, the gate and the source of each of first and second load transistors 515 and 520 of differential amplifier 500 of FIG. 5 are connected to one another. When the gate and the source of each of first and second load transistors 515 and 520 are connected to one another, as shown in FIG. 5, load transistors 515 and 520 operate as if they were in a depletion mode where a threshold voltage is less than 0 (i.e., Vth<0).

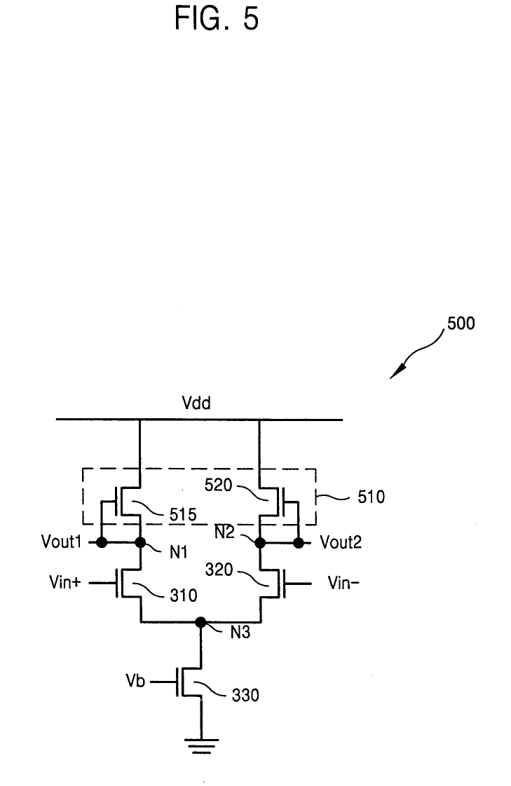

FIG. 6 is a perspective view of differential amplifier 500 formed on a silicon substrate in accordance with an embodiment of the invention. For the reasons discussed previously, differential amplifier 500 is wired so that the drain of each vertical transistor in differential amplifier 500 is at the top of the vertical transistor and the source of each vertical transistor is at the bottom.

Referring to FIG. 6, amplification transistors 310 and 320, current source transistors 330′, and load transistors 515 and 520 each comprise at least one vertical transistor, and each of those vertical transistors is connected such that the top of the vertical transistor becomes the drain and the bottom becomes the source. In more detail, load 510 comprises four vertical transistors, i.e., four load transistors, which are first and second load transistors 515′ and 520′. First load transistor 515 comprises first vertical load transistors 515′ and second load transistor 520 comprises second vertical load transistors 520′. Tops 511 and 521 of first and second vertical load transistors 515′ and 520′ are drains and are connected to first power supply Vdd. Wiring 361 connects tops 511 and 521 of first and second vertical load transistors 515′ and 520′ to first power supply Vdd. Gates 512 of first vertical load transistors 515′ are connected to differential output node 381 and gates 512 of second vertical load transistors 520′ are connected to differential output node 382. Bottoms 513 of first vertical load transistors 515′ are sources and are connected to differential output node 381 through wiring 391. Bottoms (not shown) of second vertical load transistors 520′ are sources and are connected to differential output node 382 through wiring 392. Top 311 of amplification transistor 310 (which is a vertical transistor) is connected to differential output node 381 and bottom 313 of amplification transistor 310 is connected to tops 331 of current source transistors 330′ through wirings 393 and 394. Likewise, top 321 of amplification transistor 320 (which is a vertical transistor) is connected to differential output node 382 and bottom 323 of amplification transistor 320 is connected to tops 331 of current source transistors 330′ through wirings 393 and 394. First differential input signal Vin+ is input to gate 312 of amplification transistor 310 and second differential input signal Vin− is input to gate 322 of amplification transistor 320.

Current source 330 comprises four vertical transistors, i.e., four current source transistors, which are current source transistors 330′. Bottoms 333 of current source transistors 330′ are connected to second power supply (i.e., a ground voltage) GND through wiring 395. Bias voltage Vb is input to gates 332 of current source transistors 330′.

The wiring arrangement described above, which may be used to establish the positions of a source and a drain in a vertical transistor, may also be used in a logic circuit that comprises one or more vertical transistors and generates a logical output signal in response to a logical input signal. To implement the wiring arrangement described above in a logic circuit comprising a P-channel vertical transistor, the bottom of the P-channel vertical transistor is preferably connected to a node having a higher potential than a node to which the top of the P-channel vertical transistor is connected. That is, the top of the P-channel vertical transistor preferably becomes a drain and the bottom preferably becomes a source. To implement the wiring arrangement described above in a logic circuit comprising an N-channel vertical transistor, the top of the N-channel vertical transistor is preferably connected to a node having a higher potential than a node to which the bottom is connected. That is, the top of the N-channel vertical transistor preferably becomes a drain and the bottom preferably becomes a source.

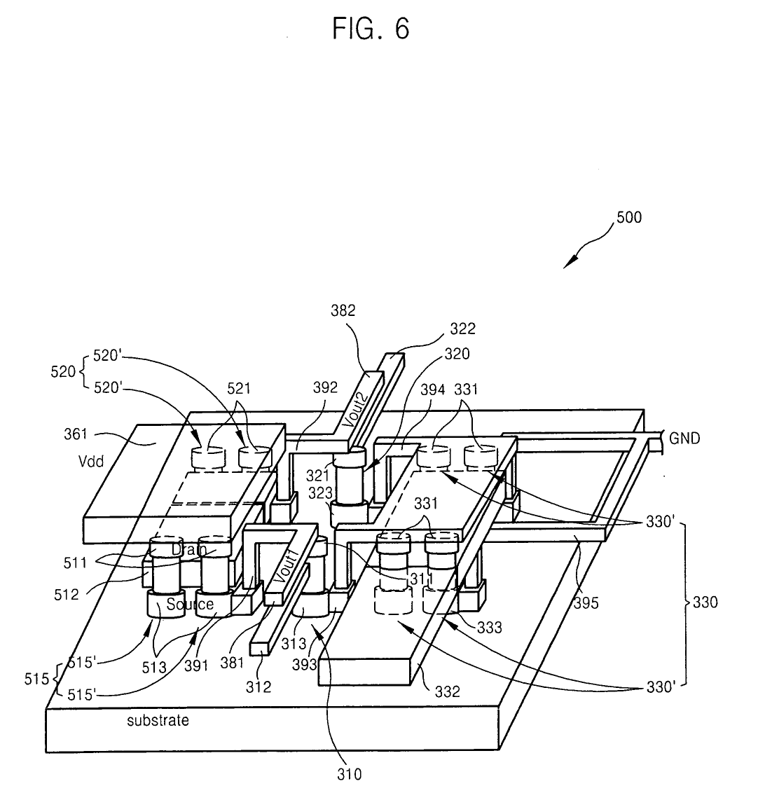

FIG. 7 is a circuit diagram of an inverter 700 in accordance with an embodiment of the invention. Inverter 700 comprises a first transistor P70 and a second transistor N70, each of which is implemented using a vertical transistor.

First transistor P70 is a P-channel transistor, a bottom of first transistor P70 becomes a source 711 connected to a first power supply Vdd, and a top of first transistor P70 becomes a drain 712 connected to an output node 731. Also, first transistor P70 receives an input signal IN through a gate 713. Second transistor N70 is an N-channel transistor, a top of second transistor N70 becomes a drain 721 connected to the output node 731 and a bottom of second transistor N70 becomes a source 722 connected to a second power supply (i.e., a ground supply). In addition, second transistor N70 receives input signal IN through a gate 723. Inverter 700 inverts input signal IN and outputs an inverted signal OUT through output node 731.

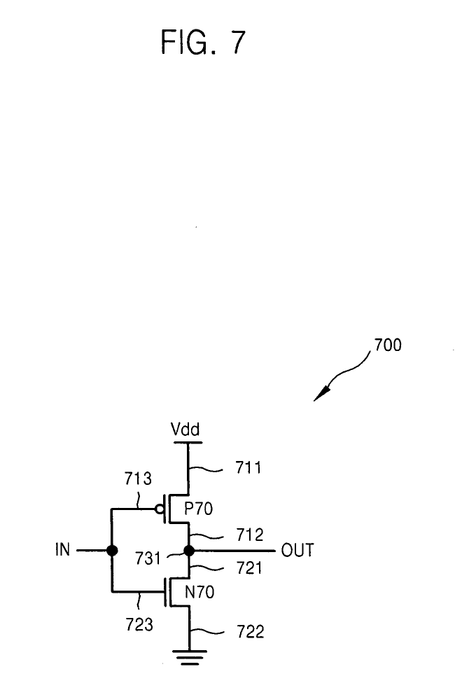

FIG. 8 is a circuit diagram of a NAND gate 800 in accordance with an embodiment of the invention. NAND gate 800 comprises first through fourth transistors P81, N81, P82, and N82, each of which is a vertical transistor.

First transistor P81 is a P-channel transistor, a bottom of first transistor P81 becomes a source 811 connected to a first power supply Vdd, and a top of first transistor P81 becomes a drain 812 connected to an output node 851. Also, first transistor P81 receives a first logical input signal IA through a gate 813. Second transistor N81 is an N-channel transistor, a top of second transistor N81 becomes a drain 831 connected to output node 851, and a bottom of second transistor N81 becomes a source 832. In addition, second transistor N81 receives first logical input signal IA through a gate 833. Third transistor P82 is a P-channel transistor, a bottom of third transistor P82 becomes a source 821 connected to first power supply Vdd, and a top of third transistor P82 becomes a drain 822 connected to output node 851. Additionally, third transistor P82 receives a second logical input signal IB through a gate 823. Fourth transistor N82 is an N-channel transistor, a top of fourth transistor N82 becomes a drain 841 connected to the bottom (i.e., source 832) of second transistor N81, and a bottom of fourth transistor N82 becomes a source 842 connected to a ground voltage. Also, fourth transistor N82 receives second logical input signal IB through a gate 843. NAND gate 800 outputs, through output node 851, a NAND signal DOUT obtained by performing a NAND operation on first logical input signal IA and second logical input signal IB.

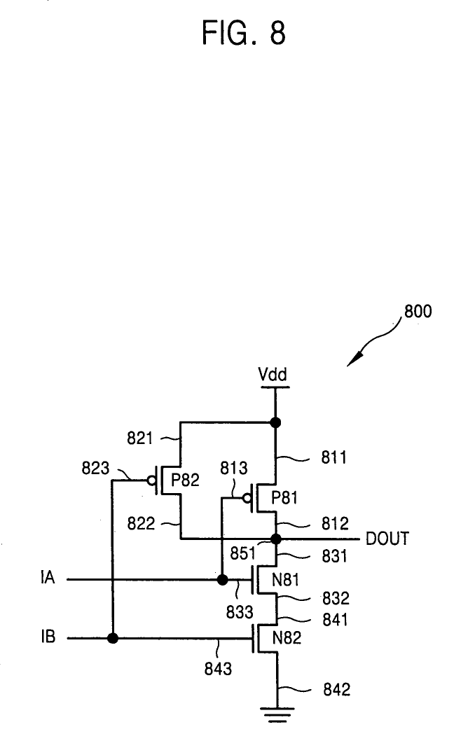

FIG. 9 is a circuit diagram of a NOR gate 900 in accordance with an embodiment of the invention. NOR gate 900 comprises first through fourth transistors P91, N91, P92, and N92, each of which is a vertical transistor.

First transistor P91 is a P-channel transistor, a bottom of first transistor P91 becomes a source 911 connected to a first power supply Vdd, and a top of first transistor P91 becomes a drain 912. Also, first transistor P91 receives a first logical input signal IC through a gate 913. Second transistor N91 is an N-channel transistor, a top of second transistor N91 becomes a drain 931 connected to an output node 951, and a bottom of second transistor N91 becomes a source 932 connected to a ground voltage. In addition, second transistor N91 receives first logical input signal IC through a gate 933. Third transistor P92 is a P-channel transistor, a bottom of third transistor P92 becomes a source 921 connected to the top (i.e., drain 912) of first transistor P91, and a top of third transistor P92 becomes a drain 922 connected to output node 951. Additionally, third transistor P92 receives a second logical input signal ID through a gate 923. Fourth transistor N92 is an N-channel transistor, a top of fourth transistor N92 becomes a drain 941 connected to output node 951, and a bottom of fourth transistor N92 becomes a source 942 connected to the ground voltage. Fourth transistor N92 also receives second logic input signal ID through a gate 943. NOR gate 900 outputs, through output node 951, a NOR signal ROUT obtained by performing a NOR operation on first logical input signal IC and second logical input signal ID.

As described above, semiconductor circuits in accordance with embodiments of the invention comprise vertical transistors, thereby reducing the surface area occupied by the circuits in a semiconductor device and increasing the integration density of the semiconductor device. In addition, in accordance with embodiments of the invention, positions of sources and drains of vertical transistors are established such that electrical characteristics of the circuits in which the vertical transistors are used may be improved.

While embodiments of the invention have been described herein with, various changes in form and details may be made to the embodiments by one of ordinary skill in the art without departing from the scope of the invention as defined by the accompanying claims.

What is claimed is:

1. A differential amplifier circuit comprising:
a pair of amplification transistors, wherein the pair of amplification transistors comprises a first amplification transistor adapted to receive, amplify, and output a differential input signal; and,
a current source electrically disposed between the pair of amplification transistors and a second power supply to form a current path between a first power supply and the second power supply,
wherein the first amplification transistor is a first vertical transistor comprising a first top and a first bottom, and wherein the first top is a first drain of the first vertical transistor and the first bottom is a first source of the first vertical transistor.

2. The circuit of claim 1, further comprising:
a load electrically disposed between the first power supply and the pair of amplification transistors,
wherein the first amplification transistor comprises at least one terminal.

3. The circuit of claim 2, wherein the load comprises a load transistor, wherein:
the load transistor comprises a first terminal connected to the first power supply, a second terminal connected to the first power supply, and a third terminal connected to one of the at least one terminal of the first amplification transistor; and,
the load transistor is a second vertical transistor comprising a second top and a second bottom, wherein the second top is a second drain of the second vertical transistor and the second bottom is a second source of the second vertical transistor.

4. The circuit of claim 2, wherein the load comprises a load transistor, wherein:
the load transistor comprises a first terminal connected to the first power supply, and second and third terminals connected to one of the at least one terminal of the first amplification transistor; and,
the load transistors is a second vertical transistor comprising a second top and a second bottom, wherein the second top is a second drain of the second vertical transistor and the second bottom is a second source of the second vertical transistor.

5. The circuit of claim 2, wherein:
the current source comprises a current source transistor comprising a first terminal connected to one of the at least one terminal of the first amplification transistor, a second terminal connected to the second power supply, and a third terminal adapted to receive a bias voltage; and,
the current source transistor is a second vertical transistor comprising a second top and a second bottom, wherein the second top is a second drain of the second vertical transistor and the second bottom is a second source of the second vertical transistor.

6. The circuit of claim 1, wherein:
the first amplification transistor is an N-channel transistor, the first bottom is connected to a first node, and the first top is connected to a second node having a higher potential than the first node; or,
the first amplification transistor is a P-channel transistor, the first top is connected to a third node, and the first bottom is connected to a fourth node having a higher potential than the third node.

7. The circuit of claim 6, further comprising:
a load transistor electrically disposed between the first power supply and the first amplification transistor, wherein the load transistor is a second vertical transistor comprising a second top and a second bottom, and the first amplification transistor comprises at least one terminal; and, wherein:
the load transistor is an N-channel transistor, the second top is connected to the first power supply, and the second bottom is connected to one of the at least one terminal of the first amplification transistor; or,
the load transistor is a P-channel transistor, the second bottom is connected to the first power supply, and the second top is connected to one of the at least one terminal of the first amplification transistor.

8. The differential amplifier circuit of claim 6, wherein the current source comprises a current source transistor, wherein the current source transistor is a second vertical transistor comprising a second top and a second bottom, and the first amplification transistor comprises at least one terminal; and wherein:
the current source transistor is an N-channel transistor, the second top is connected to one of the at least one terminal of the first amplification transistor, and the second bottom is connected to the second power supply; or,
the current source transistor is a P-channel transistor, the second bottom is connected to one of the at least one terminal of the first amplification transistor, and the second top is connected to the second power supply.

9. A semiconductor logic circuit comprising:
a first vertical transistor comprising a first top and a first bottom, wherein the first top is a first drain of the first vertical transistor and the first bottom is a first source of the first vertical transistor; and,
a second vertical transistor comprising a second top and a second bottom, wherein the second top is a second drain of the second vertical transistor and the second bottom is a second source of the second vertical transistor,
wherein the first and second vertical transistors are adapted to generate a logical output signal in response to a first logical input signal.

10. The circuit of claim 9, wherein:
the first vertical transistor is a P-channel transistor, wherein the first top is connected to a first node and the first bottom is connected to a second node having a higher potential than the first node, and
the second vertical transistor is an N-channel transistor, wherein the second bottom is connected to a third node and the second top is connected to a fourth node having a higher potential than the third node.

11. The circuit of claim 10, wherein:
the first bottom is connected to a first power supply, the first top is connected to an output node, and a first gate of the first vertical transistor is adapted to receive the first logical input signal;
the second top is connected to the output node, the second bottom is connected to a second power supply, and a second gate of the second vertical transistor is adapted to receive the first logical input signal; and,
the output node is adapted to output the logical output signal.

12. A semiconductor logic circuit adapted to output a logical output signal in accordance with a first logical input signal comprising:
a first vertical transistor comprising a first top and a first bottom, wherein the first vertical transistor is a first P-channel transistor, the first top is connected to a first node, and the first bottom is connected to a second node having a higher potential than the first node; and,
a second vertical transistor comprising a second top and a second bottom, wherein the second vertical transistor is a first N-channel transistor, the second bottom is connected to a third node, and the second top is connected to a fourth node having a higher potential than the third node.

13. The circuit of claim 12, further comprising third and fourth vertical transistors, wherein:
the first bottom is connected to a first power supply, the first top is connected to an output node, and a first gate of the first vertical transistor is adapted to receive the first logical input signal;
the second top is connected to the output node, and a second gate of the second vertical transistor is adapted to receive the first logical input signal;
the third vertical transistor is a second P-channel transistor comprising a third bottom connected to the first power supply, a third top connected to the output node, and a third gate adapted to receive a second logical input signal;
the fourth vertical transistor is a second N-channel transistor comprising a fourth top connected to the second bottom, a fourth bottom connected to a second power supply, and a fourth gate adapted to receive the second logical input signal; and,
the output node is adapted to output the logical output signal.

14. The circuit of claim 12, further comprising third and fourth vertical transistors, wherein:
the first bottom is connected to a first power supply and a first gate of the first vertical transistor is adapted to receive the first logical input signal;
the second top is connected to an output node, the second bottom is connected to a second power supply, and a second gate of the second vertical transistor is adapted to receive the first logical input signal;
the third vertical transistor is a second P-channel transistor comprising a third bottom connected to the first top, a third top connected to the output node, and a third gate adapted to receive a second logical input signal;
the fourth vertical transistor is a second N-channel transistor comprising a fourth top connected to the output node, a fourth bottom connected to the second power supply, and a fourth gate adapted to receive the second logical input signal; and,
the output node is adapted to output the logic output signal.
